(19) United States
(12) Patent Application Publication
(10) Pub. No.: US 2017/0107609 A1
(43) Pub. Date: Apr. 20, 2017

(54) APPARATUS AND METHOD FOR MONITORING EVAPORATION OF A FILM AND APPARATUS AND METHOD FOR EVAPORATING A FILM

(71) Applicant: BOE TECHNOLOGY GROUP CO., LTD., Beijing (CN)

(72) Inventor: Minghung HSU, Beijing (CN)

(21) Appl. No.: 15/202,909

(22) Filed: Jul. 6, 2016

(30) Foreign Application Priority Data
Oct. 15, 2015 (CN) 201510665382.4

(51) Int. Cl. C23C 14/54

(52) U.S. Cl. CPC C23C 14/542

(57) ABSTRACT

The present disclosure provides an apparatus for monitoring evaporation of a film, an apparatus for evaporating a film, a method for monitoring evaporation of a film and a method for evaporating a film, which can improve accuracy in monitoring evaporation of a film. The apparatus for monitoring evaporation of a film according to an embodiment monitors evaporation of the film utilizing at least two evaporation sources, the apparatus comprising: a film thickness gauge configured to measure thickness of the film obtained through evaporation utilizing the at least two evaporation sources; a resistance measurer configured to measure resistance of the film; and a calculation unit configured to calculate concentration of a material in the film coming from one of the at least two evaporation sources based on the thickness of the film measured by the film thickness gauge and the resistance measured by the resistance measurer.

### CROSS-REFERENCE TO RELATED APPLICATION

This application claims the benefit and priority of Chinese Patent Application 201510665382.4 filed Oct. 15, 2015. The entire disclosure of the above application is incorporated herein by reference.

### FIELD

The present disclosure relates to evaporation of a film, specifically, to an apparatus for monitoring evaporation of a film, an apparatus for evaporating a film, a method for monitoring evaporation of a film and a method for evaporating a film, which can improve accuracy in monitoring evaporation of a film.

### BACKGROUND

This section provides background information related to the present disclosure which is not necessarily prior art.

Organic Light-Emitting Device (OLED), due to its characteristics such as self-luminous, high brightness, high efficiency, light and slim, wide angle of view and easy to be processed and advantages such as low driving voltage, easy to be prepared in large area and full-color display, has broad application prospect and gains intensive attention. Specifically, with respect to angle of view, it possesses wide angle of view exceeding 160 degrees from up to down and from left to right, which is suitable for viewing; it possesses good brilliance, high brightness, high contrast, which makes it has excellent picture quality; it has fast reaction speed that is at 10 μs or even below 1 μs, so that usage thereof is very convenient; target of being fully-colorized may be achieved by using RGB fluorescence material or color filter, making application thereof very wide; the advantage of achieving flexibility with plastic substrate facilitates realization of a flexible display; it has broad operating temperature, which can be −40 degree Celsius to 60 degree Celsius. Tandem White OLED, due to its characteristics such as high efficiency, being applicable to a display without Fine Metal Mask (FMM) or other complex patterned process, possesses advantages such as easy to be prepared in large area and full-color display, and is especially suitable for large sized application.

However, the above device utilizes two or more tandem light-emitting units, and a connection layer between the light-emitting units is vital to efficiency of the device. To overcome deficiencies of organic semiconductor such as energy barrier matching and low mobility ratio, a known process is to add dopant of active molecules in organic film fabrication, so as to solve the problems of energy barrier matching and low mobility ratio by raising concentration of carriers of the organic film through carriers released from the active molecules.

During evaporation of the film, evaporation material is to be monitored to conduct fabrication of the film, in which it is known to use the following monitoring manner: a common co-evaporation source device is as shown in FIG. 6, taking binary co-evaporation for example, in order to control proportion and thickness of a co-evaporated film formed on a substrate 50, for evaporation source A and evaporation source B, independent quartz film thickness gauges 21, 22 will be respectively provided on independent substrates 51, 52 according to evaporation angle, that is, film FA resulting from evaporation by evaporation source A will only be formed on quartz film thickness gauges 21 on substrate 51, and film FB resulting from evaporation by evaporation source B will only be formed on quartz film thickness gauges 22 on substrate 52. Then, thickness and proportion of two kinds of materials in the co-evaporated film evaporated on the substrate 50 may be known by calculating with independent correction factors.

### SUMMARY

This section provides a general summary of the disclosure, and is not a comprehensive disclosure of its full scope or all of its features.

Inventors of the present disclosure have found that there is following problem in the above prior art: common active material such as Mg and Li has very strong chemical activity itself and will have reaction with small amount of gas even in vacuum, thus has so-called characteristic of gas absorption. This characteristic will influence a quartz film thickness gauge that monitors thickness mainly by mass, during gas absorption, small amount of gas will be adhered to active molecule film of the quartz sheet, thus forming noise to mass monitoring, the characteristic of gas absorption is subject to vacuum degree, temperature etc, so that accuracy in monitoring thickness of the film will be decreased, furthermore, there is problem of poor monitoring stability in case of low evaporation rate.

FIG. 7 is a diagram for illustrating mechanism of a problem existed in monitoring evaporation of a conventional co-evaporated film. Taking a case in which Mg is evaporated by the evaporation source B for example, due to highly active metal film FB formed on the independent quartz film thickness gauge 22, molecules of oxygen gas will have reaction with Mg to become a portion of mass adhered to the film thickness gauge 22, thus forming error in monitoring. In addition, the formed magnesium oxide is also a substance that is prone to water absorption and will absorb small amount of water vapor in cavity, thus further increasing the error. Finally, since these reactions with small amount of gas in vacuum cavity are greatly influenced by vacuum degree, temperature, vacuum gas distribution in cavity etc, they will bring random and unexpected noise.

To solve the above problems in the art, embodiments of the disclosure provide an apparatus for monitoring evaporation of a film, an apparatus for evaporating a film, a method for monitoring evaporation of a film and a method for evaporating a film, which can improve accuracy in film thickness monitoring by suppressing formation of noise in monitoring evaporation of a film.

Specifically, the following technical solutions are provided.

[1] An apparatus for monitoring evaporation of a film, wherein, evaporation of the film utilizing at least two evaporation sources is being monitored, the apparatus comprising:

a film thickness gauge configured to measure thickness of the film obtained through evaporation utilizing the at least two evaporation sources;

a resistance measurer configured to measure resistance of the film; and

a calculation unit configured to calculate concentration of a material in the film coming from one of the at least two evaporation sources based on the thickness of the film measured by the film thickness gauge and the resistance measured by the resistance measurer.

The apparatus for monitoring evaporation of a film according to [1] is configured to obtain concentration of evaporation material by monitoring thickness and resistance of doped evaporation film, thus is capable of avoiding noise to monitoring when separately monitoring evaporation material, further, concentration of evaporation material can be accurately obtained by measuring characteristic of resistance.

[2] The apparatus according to [1], wherein, the calculation unit is configured to calculate resistivity of the film by using equations (1) and (2) based on the thickness and the resistance of the film,

$$\begin{matrix}\frac{1}{R\_total} = \frac{1}{R\_ 0} + \frac{1}{Δ R} & equation ( 1 ) \\ Δ R = \frac{ρ A}{Δ d} & equation ( 2 )\end{matrix}$$

wherein, R_0 denotes resistance measured at t=0, R_total denotes resistance measured at t=Δt, Δd denotes a difference between the thickness at t=Δt and the thickness at t=0, A denotes area of the resistance measurer, ρ denotes resistivity of the film evaporated during t=0 to t=Δt,

the calculation unit is configured to calculate concentration of the material based on previously acquired relationship between the resistivity and the concentration of the material.

The apparatus according to [2] is configured to calculate resistivity by using the equations according to thickness and resistance of the film, and further calculate concentration of evaporation material by referring to correspondence therebetween, and thus is capable of accurately obtaining concentration of evaporation material from measured values.

[3] The apparatus according to [1] or [2], wherein, the resistance measurer is a probe resistance measurer configured to measure sheet resistance of the film.

The apparatus according to [3] is capable of increasing measurement accuracy by taking a probe resistance measurer as the resistance measurer.

[4] The apparatus according to [3], wherein, a semiconductor film is provided on a probe of the probe resistance measurer.

The apparatus according to [4] is capable of ensuring measurement stability by providing a semiconductor film on a probe of the probe resistance measurer.

[5] The apparatus according to [4], wherein, material of the semiconductor film is selected from any one of monocrystalline silicon, metal oxide semiconductor, three-five semiconductor and organic semiconductor or is any combination of the above materials.

The apparatus according to [5], in which sheet resistance of semiconductor film material is approximately equal to sheet resistance of a film at upper limit of monitored thickness, is capable of making measurement more stable.

[6] The apparatus according to [3], wherein, the probe resistance measurer is a four-point probe resistance measurer.

The apparatus according to [6] is capable of increasing measurement accuracy by taking a four-point probe resistance measurer as the probe resistance measurer.

[7] The apparatus according to any one of [1] to [6], wherein, a thermostatic apparatus is provided on at least one of the film thickness gauge and the resistance measurer.

The apparatus according to [7] is capable of suppressing influence due to characteristic of gas absorption etc by employing a thermostatic apparatus during monitoring.

[8] The apparatus according to any one of [1] to [7], wherein, the at least two evaporation sources comprise an active material evaporation source and an organic material evaporation source.

The apparatus according to [8] is capable of making improvement in monitoring accuracy more significant by making the at least two evaporation sources comprise an active material evaporation source and an organic material evaporation source.

[9] The apparatus according to [8], wherein, active material in the active material evaporation source is selected from any one of rare earth metal, alkali metal, alkaline earth metal, organic material and a material having high water absorption or is any combination of the above materials.

[10] The apparatus according to [9], wherein, the rare earth metal is Yb.

[11] The apparatus according to [9], wherein, the alkali metal is Li.

[12] The apparatus according to [9], wherein, the alkaline earth metal is Ca or Mg.

[13] The apparatus according to [9], wherein, the material having high water absorption is alkali metal oxide or alkaline earth metal oxide.

The apparatus according to [9] to [13] is capable of making improvement in monitoring accuracy more significant by making the active material to be the above preferred material.

[14] The apparatus according to any one of [1] to [13], wherein, the film thickness gauge is a quartz film thickness gauge.

The apparatus according to [14] is capable of increasing measurement accuracy by taking a quartz film thickness gauge as the film thickness gauge.

[15] An apparatus for evaporating a film, wherein, evaporation of the film is monitored by using the apparatus for monitoring evaporation of a film according to any one of [1] to [14].

The apparatus for evaporating a film according to [15] is capable of accurately obtaining concentration of evaporation material by using the apparatus for monitoring evaporation of a film according to any one of [1] to [14], and thus is capable of making film thickness control more accurate, and making mass production to be controlled more easily.

[16] A method for monitoring evaporation of a film, wherein, evaporation of the film utilizing at least two evaporation sources is being monitored, the method comprising: a thickness measuring step of measuring thickness of the film obtained through evaporation utilizing the at least two evaporation sources; a resistance measuring step of measuring resistance of the film; and a calculating step of calculating concentration of a material in the film coming from one of the at least two evaporation sources based on the thickness of the film obtained in the thickness measuring step and the resistance obtained in the resistance measuring step.

The method for monitoring evaporation of a film according to [16] is capable of obtaining concentration of evaporation material by monitoring thickness and resistance of doped evaporation film, and thus is capable of avoiding noise to monitoring when separately monitoring evaporation material, further, concentration of evaporation material can be accurately obtained by measuring characteristic of resistance.

[17] The method according to [16], wherein, in the calculating step, resistivity of the film is calculated by using equations (1) and (2) based on the thickness and the resistance of the film,

$$\begin{matrix}\frac{1}{R\_total} = \frac{1}{R\_ 0} + \frac{1}{Δ R} & equation ( 1 ) \\ Δ R = \frac{ρ A}{Δ d} & equation ( 2 )\end{matrix}$$

wherein, R_0 denotes resistance measured at t=0, R_total denotes resistance measured at t=Δt, Δd denotes a difference between the thickness at t=Δt and the thickness at t=0, A denotes area of the resistance measurer, ρ denotes resistivity of the film evaporated during t=0 to t=Δt,

in the calculating step, concentration of the material is calculated based on previously acquired relationship between the resistivity and the concentration of the material.

The method according to [17] is capable of calculating resistivity by using the equations according to thickness and resistance of the film, and further calculating concentration of evaporation material by referring to correspondence therebetween, and thus is capable of accurately obtaining concentration of evaporation material from measured values.

[18] The method according to [16] or [17], wherein, a probe resistance measurer is employed in the resistance measuring step to measure sheet resistance of the film.

The method according to [18] is capable of increasing measurement accuracy by employing a probe resistance measurer in the resistance measuring step to measure sheet resistance of the film.

[19] The method according to [18], wherein, a semiconductor film is provided on a probe of the probe resistance measurer.

The method according to [19] is capable of ensuring measurement stability by providing a semiconductor film on a probe of the probe resistance measurer.

[20] The method according to [19], wherein, material of the semiconductor film is selected from any one of monocrystalline silicon, metal oxide semiconductor, three-five semiconductor and organic semiconductor or is any combination of the above materials.

The method according to [20], in which sheet resistance of semiconductor film material is approximately equal to sheet resistance of a film at upper limit of monitored thickness, is capable of making measurement more stable.

[21] The method according to [18], wherein, the probe resistance measurer is a four-point probe resistance measurer.

The method according to [21] is capable of increasing measurement accuracy by taking a four-point probe resistance measurer as the probe resistance measurer.

[22] The method according to any one of [16] to [21], wherein, a thermostatic apparatus is employed in at least one of the thickness measuring step and the resistance measuring step.

The method according to [22] is capable of suppressing influence due to characteristic of gas absorption etc by employing a thermostatic apparatus during monitoring.

[23] The method according to any one of [16] to [22], wherein, the at least two evaporation sources comprise an active material evaporation source and an organic material evaporation source.

The method according to [23] is capable of making improvement in monitoring accuracy more significant by making the at least two evaporation sources comprise an active material evaporation source and an organic material evaporation source.

[24] The method according to [23], wherein, active material in the active material evaporation source is selected from any one of rare earth metal, alkali metal, alkaline earth metal, organic material and a material having high water absorption or is any combination of the above materials.

[25] The method according to [24], wherein, the rare earth metal is Yb.

[26] The method according to [24], wherein, the alkali metal is Li.

[27] The method according to [24], wherein, the alkaline earth metal is Ca or Mg.

[28] The method according to [24], wherein, the material having high water absorption is alkali metal oxide or alkaline earth metal oxide.

The method according to [24] to [28] is capable of making improvement in monitoring accuracy more significant by making the active material to be the above preferred material.

[29] The method according to any one of [16] to [28], wherein, a quartz film thickness gauge is employed in the thickness measuring step.

[30] A method for evaporating a film, wherein, evaporation of the film is monitored by using the method for monitoring evaporation of a film according to any one of [16] to [29].

The method for evaporating a film according to [30] is capable of accurately obtaining concentration of evaporation material by using the method for monitoring evaporation of a film according to any one of [16] to [29], and thus is capable of making film thickness control more accurate, and making mass production to be controlled more easily.

Further aspects and areas of applicability will become apparent from the description provided herein. It should be understood that various aspects of this disclosure may be implemented individually or in combination with one or more other aspects. It should also be understood that the description and specific examples herein are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a block diagram formed by an apparatus for monitoring evaporation of a film according to an embodiment of the disclosure.

FIG. 2 is a diagram showing measurement on a film obtained through evaporation by using the apparatus for monitoring evaporation of a film according to an embodiment of the disclosure.

FIG. 3 is a schematic diagram showing the relationship between resistance and concentration.

FIG. 4 is a flowchart showing process of a method for monitoring evaporation of a film according to an embodiment of the disclosure.

FIG. 5 is a flowchart illustrating process of calculating concentration of material by using measured values.

FIG. 6 is a diagram showing measurement on a film by using an apparatus for monitoring evaporation of a conventional co-evaporated film.

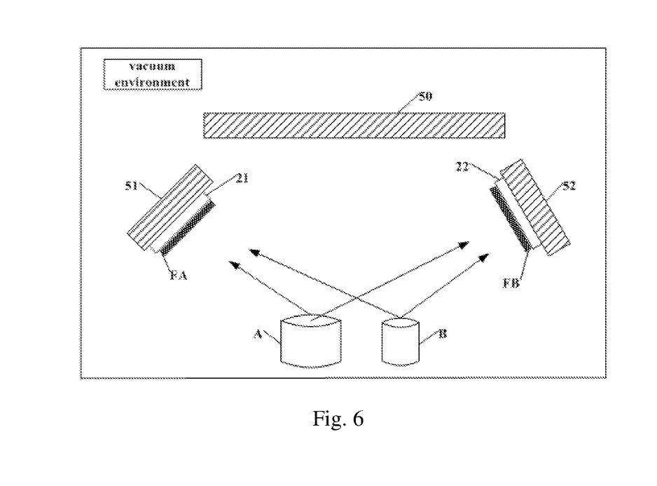

FIG. 7 is a diagram for illustrating mechanism of a problem existed in monitoring evaporation of a conventional co-evaporated film.

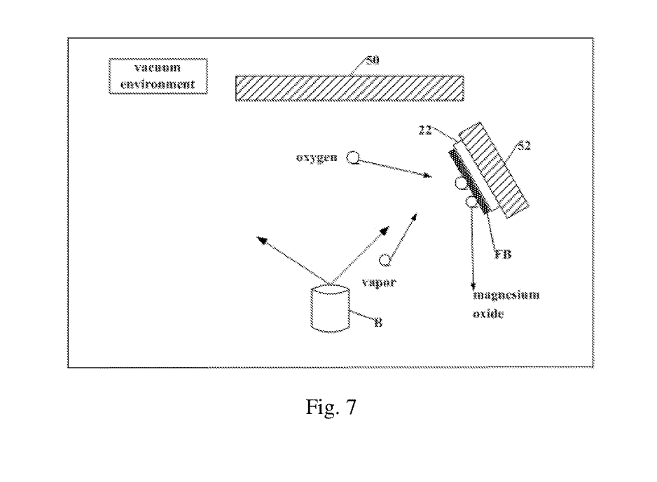

Corresponding reference numerals indicate corresponding parts or features throughout the several views of the drawings.

### DETAILED DESCRIPTION

Example embodiments will now be described more fully with reference to the accompanying drawings.

To make objects, technical solutions and advantages of embodiments of the disclosure more apparent, the technical solutions of the embodiments of the disclosure will be described below clearly and completely in connection with the drawings. Apparently, the described embodiments are just part of rather than all of the embodiments of the disclosure. Based on the described embodiments, all other embodiments obtained by those skilled in the art without any inventive work are within protection scope of the disclosure.

In description of the disclosure, it should be noted that, orientation or positional relationship indicated by terms such as “up”, “down”, “top” and “bottom” are orientation or positional relationship shown based on the drawings. These terms are only for convenience of description and for simplifying description, and do not indicate or imply that the apparatus or element referred must have particular orientation, being constructed or operated in particular orientation, thus, they should not be construed to be limitation on the present disclosure.

In addition, in description of the disclosure, unless otherwise indicated, meaning of “a plurality of” refers to two or more than two.

Next, various preferred embodiments of the disclosure will be described in detail in conjunction with drawings.

An Apparatus for Monitoring Evaporation of a Film and an Apparatus for Evaporating a Film

The present embodiment provides an apparatus for monitoring evaporation of a film, wherein, evaporation of the film utilizing at least two evaporation sources is being monitored, the apparatus comprising: a film thickness gauge configured to measure thickness of the film obtained through evaporation utilizing the at least two evaporation sources; a resistance measurer configured to measure resistance of the film; and a calculation unit configured to calculate concentration of a material in the film coming from one of the at least two evaporation sources based on the thickness of the film measured by the film thickness gauge and the resistance measured by the resistance measurer.

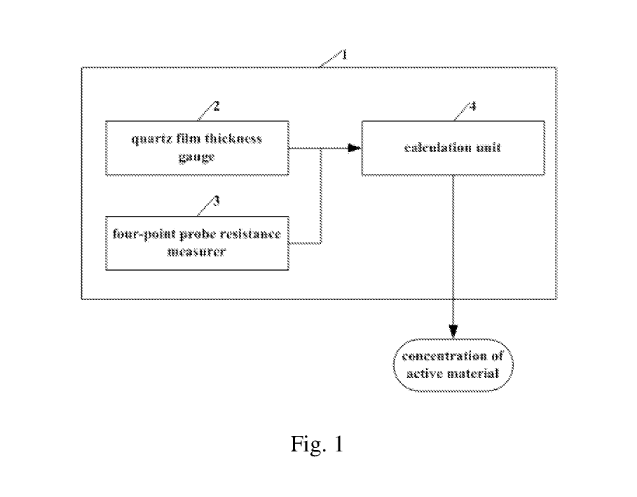

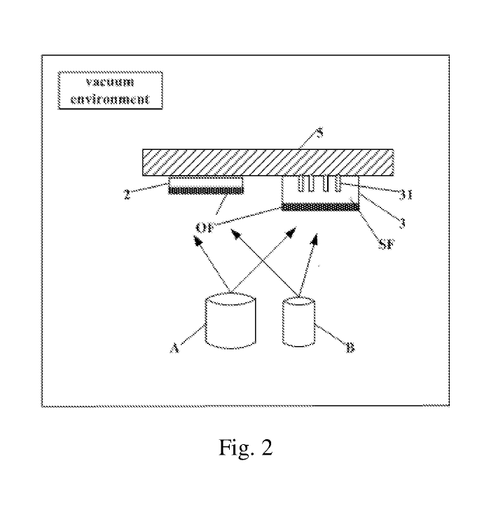

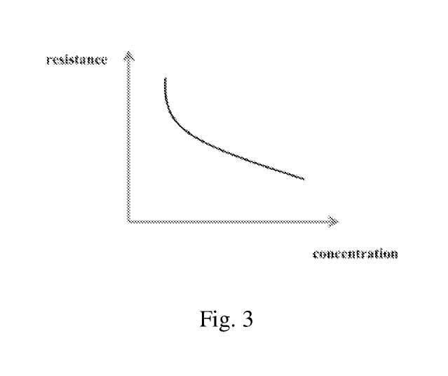

Next, detailed description will be made by taking FIG. 1 to FIG. 3 for example. FIG. 1 is a block diagram formed by an apparatus for monitoring evaporation of a film according to an embodiment of the disclosure. FIG. 2 is a diagram showing measurement on a film obtained through evaporation by using the apparatus for monitoring evaporation of a film according to an embodiment of the disclosure. FIG. 3 is a schematic diagram showing the relationship between resistance and concentration.

As shown in FIG. 1 and FIG. 2, the apparatus 1 for monitoring evaporation of a film according to the present embodiment is preferably configured to monitor evaporation of the film utilizing an organic material evaporation source A and an active doping material evaporation source B, the apparatus preferably comprising: a quartz film thickness gauge 2, a four-point probe sheet resistance measurer 3 and a calculation unit 4. Wherein, the active doping material is preferably selected from any one of rare earth metal, alkali metal, alkaline earth metal, organic material and a material having high water absorption or is any combination of the above materials. Further, the rare earth metal is preferably Yb, the alkali metal is preferably Li, the alkaline earth metal is preferably Ca or Mg, and the material having high water absorption is preferably alkali metal oxide or alkaline earth metal oxide.

As shown in FIG. 2, the quartz film thickness gauge 2 and the four-point probe sheet resistance measurer 3 are provided on a substrate 5 at position to which organic material and active doping material can be evaporated simultaneously according to evaporation angle, the quartz film thickness gauge 2 is configured to measure thickness of organic doping film OF obtained through evaporation, and the four-point probe sheet resistance measurer 3 is configured to measure sheet resistance of the organic doping film OF.

Since the organic doping film OF on the quartz film thickness gauge 2 and the four-point probe sheet resistance measurer 3 is a mixture of two kinds of material, actually the active material will be covered by the mixture, such that reactivity of surface of the final organic doping film OF is significantly reduced, and meanwhile, since doping concentration where active material is applied is generally not very large, and combination of organic doping film OF is mainly comprised of stable organic material, reliable mass and thickness can be obtained by the quartz film thickness gauge 2.

On the other hand, since carriers will be released from active material, carrier concentration of the organic doping film OF will be increased and characteristic of resistance will be changed, that is, contribution of active material to mass of the organic doping film OF is not very large, but it has great influence on characteristic of resistance of the organic doping film OF, therefore, relative thickness or proportion of active material may be monitored by measuring sheet resistance of the organic doping film OF with the four-point probe sheet resistance measurer 3.

Moreover, when measuring sheet resistance of the organic doping film OF by applying the four-point probe sheet resistance measurer 3, to ensure stability in measurement, a semiconductor film SF is preferably provided on probe electrodes 31 of the four-point probe sheet resistance measurer 3. Sheet resistance of the semiconductor film SF is approximately equal to sheet resistance of the organic doping film at upper limit of monitored thickness, and material of the semiconductor film SF is preferably selected from any one of monocrystalline silicon, metal oxide semiconductor, three-five semiconductor and organic semiconductor or is any combination of the above materials.

In the apparatus 1 for monitoring evaporation of a film according to the present embodiment, after thickness and sheet resistance of the organic doping film OF are respectively measured by the quartz film thickness gauge 2 and the four-point probe sheet resistance measurer 3, the measured thickness value and sheet resistance value are respectively inputted into the calculation unit 4, which calculates resistivity of the film by using equations (1) and (2) based on the thickness value and sheet resistance value,

$$\begin{matrix}\frac{1}{R\_total} = \frac{1}{R\_ 0} + \frac{1}{Δ R} & equation ( 1 ) \\ Δ R = \frac{ρ A}{Δ d} & equation ( 2 )\end{matrix}$$

wherein, R_0 denotes sheet resistance measured at t=0, R_total denotes sheet resistance measured at t=Δt, Δd (within a small range, it may be assumed that thickness on the quartz film thickness gauge and the four-point probe are the same) denotes a difference between the thickness at t=Δt and the thickness at t=0, A denotes area of the four-point probe sheet resistance measurer 3, ρ denotes resistivity of the film evaporated between t=0 and t=Δt.

After resistivity of the organic doping film OF is calculated through the above equations, the calculation unit 4 is configured to calculate concentration of the active material based on a chart as shown in FIG. 3 acquired through previous experiments that denotes a relationship between resistance and concentration of the active material.

The apparatus for monitoring evaporation of a film according to the present embodiment is configured to obtain concentration of active material by monitoring thickness and sheet resistance of an organic doping film OF obtained through evaporation, thus is capable of avoiding noise to monitoring when separately monitoring active material, further, concentration of active material can be accurately obtained by measuring characteristic of resistance. Furthermore, it is configured to calculate resistivity by using the equations according to thickness and resistance of the film, and further calculate concentration of evaporation material by referring to correspondence therebetween, and thus is capable of accurately obtaining concentration of evaporation material from measured values. Further, it is capable of increasing measurement accuracy by taking a probe resistance measurer as the resistance measurer. Further, it is capable of ensuring measurement stability by providing a semiconductor film on a probe of the probe resistance measurer. Further, by making material of the semiconductor film be preferably selected from any one of monocrystalline silicon, metal oxide semiconductor, three-five semiconductor and organic semiconductor or be any combination of the above materials, thus making sheet resistance of semiconductor film material approximately equal to sheet resistance of a film at upper limit of monitored thickness, it is capable of making measurement more stable. Further, it is capable of increasing measurement accuracy by taking a four-point probe resistance measurer as the probe resistance measurer. Further, since reaction between active material and small amount of gas in vacuum cavity is greatly influenced by vacuum degree, temperature, vacuum gas distribution in cavity etc, a thermostatic apparatus is preferably provided for at least one of the film thickness gauge and the four-point probe sheet resistance measurer, thus it is capable of suppressing influence due to characteristic of gas absorption, such that monitoring accuracy is improved.

Moreover, the at least two evaporation sources comprise an active material evaporation source and an organic material evaporation source, active material in the active material evaporation source is preferably selected from any one of rare earth metal, alkali metal, alkaline earth metal, organic material and a material having high water absorption or is any combination of the above materials, the rare earth metal is preferably Yb, the alkali metal is preferably Li, the alkaline earth metal is preferably Ca or Mg, the material having high water absorption is preferably alkali metal oxide or alkaline earth metal oxide, thus, it is capable of making improvement in monitoring accuracy more significant.

Further, it is capable of increasing measurement accuracy by taking a quartz film thickness gauge as the film thickness gauge.

The apparatus for evaporating a film according to the present embodiment, by monitoring evaporation of a film with the above apparatus for monitoring evaporation of a film, is capable of achieving same effect as the above, and is capable of accurately obtaining concentration of evaporation material, thus is capable of making film thickness control more accurate, and making mass production to be controlled more easily.

A Method for Monitoring Evaporation of a Film and a Method for Evaporating a Film

The present embodiment provides a method for monitoring evaporation of a film, wherein, evaporation of the film utilizing at least two evaporation sources is being monitored, the method comprising: a thickness measuring step of measuring thickness of the film obtained through evaporation utilizing the at least two evaporation sources; a resistance measuring step of measuring resistance of the film; and a calculating step of calculating concentration of a material in the film coming from one of the at least two evaporation sources based on the thickness of the film obtained in the thickness measuring step and the resistance obtained in the resistance measuring step.

In the method for monitoring evaporation of a film related to the present embodiment, evaporation of the film utilizing an organic material evaporation source A and an active doping material evaporation source B is monitored, wherein, the active doping material is preferably selected from any one of rare earth metal, alkali metal, alkaline earth metal, organic material and a material having high water absorption or is any combination of the above materials, further, the rare earth metal is preferably Yb, the alkali metal is preferably Li, the alkaline earth metal is preferably Ca or Mg, and the material having high water absorption is preferably alkali metal oxide or alkaline earth metal oxide.

Next, the evaporation monitoring method will be described in detail.

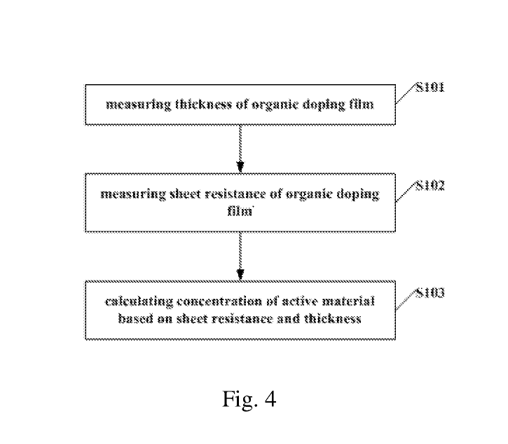

As shown in FIG. 4, first, in step S101, S102, thickness and sheet resistance of organic doping film OF obtained through evaporation are measured by using a quartz film thickness gauge 2 and a four-point probe sheet resistance measurer 3, respectively. In addition, when measuring sheet resistance of the organic doping film OF in step S102, to ensure stability of measurement, a semiconductor film is preferably used. Sheet resistance of the semiconductor film is approximately equal to sheet resistance of the organic doping film at upper limit of monitored thickness, and material of the semiconductor film is preferably selected from any one of monocrystalline silicon, metal oxide semiconductor, three-five semiconductor and organic semiconductor or is any combination of the above materials.

Further, after thickness and sheet resistance of the organic doping film OF are respectively measured, in step S103, concentration of the active material is calculated based on the thickness value and the sheet resistance value, then the process is ended.

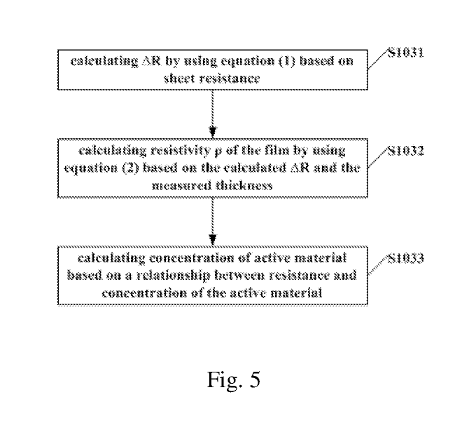

Next, the process in step S103 will be described in detail based on FIG. 5.

First, in step S1031, ΔR is calculated by using equation (1) based on the measured sheet resistance.

$$\frac{1}{R\_total} = \frac{1}{R\_ 0} + \frac{1}{Δ R} \qquad equation ( 1 )$$

wherein, R_0 denotes sheet resistance measured at t=0, R_total denotes sheet resistance measured at t=Δt.

Next, in step S1032, resistivity ρ of the film is calculated by using equation (2) based on the calculated ΔR and the measured thickness.

$$Δ R = \frac{ρ A}{Δ d} \qquad equation ( 2 )$$

wherein, Δd (within a small range, it may be assumed that thickness on the quartz film thickness gauge and the four-point probe are the same) denotes a difference between the thickness at t=Δt and the thickness at t=0, A denotes area of the four-point probe sheet resistance measurer 3, ρ denotes resistivity of the organic doping film evaporated between t=0 and t=Δt.

After resistivity ρ of the organic doping film is calculated, in step S1033, concentration of the active material is calculated based on a chart as shown in FIG. 3 acquired through previous experiments that denotes a relationship between resistance and concentration of the active material. The method for monitoring evaporation of a film according to the present embodiment is capable of obtaining concentration of active material by monitoring thickness and sheet resistance of an organic doping film obtained through evaporation, thus is capable of avoiding noise to monitoring when separately monitoring active material, further, concentration of active material can be accurately obtained by measuring characteristic of resistance. Furthermore, it is capable of calculating resistivity by using the equations according to thickness and resistance of the film, and further calculating concentration of evaporation material by referring to correspondence therebetween, and thus is capable of accurately obtaining concentration of evaporation material from measured values. Further, it is capable of increasing measurement accuracy by employing a probe resistance measurer in the resistance measuring step. Further, it is capable of ensuring measurement stability by providing a semiconductor film on a probe of the probe resistance measurer. Further, by making material of the semiconductor film be preferably selected from any one of monocrystalline silicon, metal oxide semiconductor, three-five semiconductor and organic semiconductor or be any combination of the above materials, thus making sheet resistance of semiconductor film material approximately equal to sheet resistance of a film at upper limit of monitored thickness, it is capable of making measurement more stable. Further, it is capable of increasing measurement accuracy by taking a four-point probe resistance measurer as the probe resistance measurer.

Further, since reaction between active material and small amount of gas in vacuum cavity is greatly influenced by vacuum degree, temperature, vacuum gas distribution in cavity etc, a thermostatic apparatus is preferably employed in at least one of the thickness measuring step and the sheet resistance measuring step, thus it is capable of suppressing influence due to characteristic of gas absorption, such that monitoring accuracy is improved.

Moreover, in the method for monitoring evaporation of a film according to the present embodiment, the at least two evaporation sources comprise an active material evaporation source and an organic material evaporation source, active material in the active material evaporation source is preferably selected from any one of rare earth metal, alkali metal, alkaline earth metal, organic material and a material having high water absorption or is any combination of the above materials, the rare earth metal is preferably Yb, the alkali metal is preferably Li, the alkaline earth metal is preferably Ca or Mg, the material having high water absorption is preferably alkali metal oxide or alkaline earth metal oxide, thus, it is capable of making improvement in monitoring accuracy more significant.

Further, in the method for monitoring evaporation of a film according to the present embodiment, it is capable of increasing measurement accuracy by employing a quartz film thickness gauge in the thickness measuring step.

The method for evaporating a film according to the present embodiment, by monitoring evaporation of a film with the above method for monitoring evaporation of a film, is capable of achieving same effect as the above, and is capable of accurately obtaining concentration of evaporation material, thus is capable of making film thickness control more accurate, and making mass production to be controlled more easily.

In the foregoing, in description with respect to an apparatus for monitoring evaporation of a film, an apparatus for evaporating a film, a method for monitoring evaporation of a film, and a method for evaporating a film, although the description is made by taking two evaporation sources for example, it is appreciated that there may be more than two evaporation sources in the apparatus for evaporating a film. In addition, evaporation material is described by taking organic material and active doping material for example, however, it may be any material used in the film. In addition, the film thickness gauge is described by taking a quartz film thickness gauge for example, however, the film thickness gauge may be any film thickness gauge known to those skilled in the art, as long as thickness of a film can be measured. In addition, the resistance measurer is described by taking a probe resistance measurer for example, and the probe resistance measurer is described by taking a four-point probe sheet resistance measurer for example, however, the resistance measurer can be other resistance measurer as long as it can measure resistance or sheet resistance of a film.

Although detailed embodiments of the disclosure have been described above through some exemplary embodiments, the above embodiments are not exhaustive and those skilled in the art can realize various changes and modifications within spirit and scope of the present disclosure. Therefore, the present disclosure is not limited to these embodiment, and the scope of which is only defined by the accompany claims.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. An apparatus for monitoring evaporation of a film, wherein, evaporation of the film utilizing at least two evaporation sources is being monitored, the apparatus comprising:
a film thickness gauge configured to measure thickness of the film obtained through evaporation utilizing the at least two evaporation sources;
a resistance measurer configured to measure resistance of the film; and
a calculation unit configured to calculate concentration of a material in the film coming from one of the at least two evaporation sources based on the thickness of the film measured by the film thickness gauge and the resistance measured by the resistance measurer.

2. The apparatus for monitoring evaporation of a film according to claim 1, wherein, the calculation unit is configured to calculate resistivity of the film by using equations (1) and (2) based on the thickness and the resistance of the film,
$$\begin{matrix}\frac{1}{R\_total} = \frac{1}{R\_ 0} + \frac{1}{Δ R} & equation ( 1 ) \\ Δ R = \frac{ρ A}{Δ d} & equation ( 2 )\end{matrix}$$
wherein, R_0 denotes resistance measured at t=0, R_total denotes resistance measured at t=Δt, Δd denotes a difference between the thickness at t=Δt and the thickness at t=0, A denotes area of the resistance measurer, ρ denotes resistivity of the film evaporated during t=0 to t=Δt,
the calculation unit is configured to calculate concentration of the material based on previously acquired relationship between the resistivity and the concentration of the material.

3. The apparatus for monitoring evaporation of a film according to claim 1, wherein, the resistance measurer is a probe resistance measurer configured to measure sheet resistance of the film.

4. The apparatus for monitoring evaporation of a film according to claim 3, wherein, a semiconductor film is provided on a probe of the probe resistance measurer, material of the semiconductor film is selected from any one of monocrystalline silicon, metal oxide semiconductor, three-five semiconductor and organic semiconductor or is any combination of the above materials.

5. The apparatus for monitoring evaporation of a film according to claim 3, wherein, the probe resistance measurer is a four-point probe resistance measurer.

6. The apparatus for monitoring evaporation of a film according to claim 1, wherein, a thermostatic apparatus is provided on at least one of the film thickness gauge and the resistance measurer.

7. The apparatus for monitoring evaporation of a film according to claim 1, wherein, the at least two evaporation sources comprise an active material evaporation source and an organic material evaporation source, active material in the active material evaporation source is selected from any one of rare earth metal, alkali metal, alkaline earth metal, organic material and a material having high water absorption or is any combination of the above materials.

8. The apparatus for monitoring evaporation of a film according to claim 7, wherein, the rare earth metal is Yb, or the alkali metal is Li, or the alkaline earth metal is Ca or Mg, or the material having high water absorption is alkali metal oxide or alkaline earth metal oxide.

9. The apparatus for monitoring evaporation of a film according to claim 1, wherein, the film thickness gauge is a quartz film thickness gauge.

10. An apparatus for evaporating a film, wherein, evaporation of the film is monitored by using the apparatus for monitoring evaporation of a film according to any one of claim 1.

11. A method for monitoring evaporation of a film, wherein, evaporation of the film utilizing at least two evaporation sources is being monitored, the method comprising:
a thickness measuring step of measuring thickness of the film obtained through evaporation utilizing the at least two evaporation sources;
a resistance measuring step of measuring resistance of the film; and
a calculating step of calculating concentration of a material in the film coming from one of the at least two evaporation sources based on the thickness of the film obtained in the thickness measuring step and the resistance obtained in the resistance measuring step.

12. The method for monitoring evaporation of a film according to claim 11, wherein, in the calculating step, resistivity of the film is calculated by using equations (1) and (2) based on the thickness and the resistance of the film,
$$\begin{matrix}\frac{1}{R\_total} = \frac{1}{R\_ 0} + \frac{1}{Δ R} & equation ( 1 ) \\ Δ R = \frac{ρ A}{Δ d} & equation ( 2 )\end{matrix}$$
wherein, R_0 denotes resistance measured at t=0, R_total denotes resistance measured at t=Δt, Δd denotes a difference between the thickness at t=Δt and the thickness at t=0, A denotes area of the resistance measurer, ρ denotes resistivity of the film evaporated during t=0 to t=Δt,
in the calculating step, concentration of the material is calculated based on previously acquired relationship between the resistivity and the concentration of the material.

13. The method for monitoring evaporation of a film according to claim 11, wherein, a probe resistance measurer is employed in the resistance measuring step to measure sheet resistance of the film.

14. The method for monitoring evaporation of a film according to claim 13, wherein, a semiconductor film is provided on a probe of the probe resistance measurer, material of the semiconductor film is selected from any one of monocrystalline silicon, metal oxide semiconductor, three-five semiconductor and organic semiconductor or is any combination of the above materials.

15. The method for monitoring evaporation of a film according to claim 13, wherein, the probe resistance measurer is a four-point probe resistance measurer.

16. The method for monitoring evaporation of a film according to claim 11, wherein, a thermostatic apparatus is employed in at least one of the thickness measuring step and the resistance measuring step.

17. The method for monitoring evaporation of a film according to claim 11, wherein, the at least two evaporation sources comprise an active material evaporation source and an organic material evaporation source, active material in the active material evaporation source is selected from any one of rare earth metal, alkali metal, alkaline earth metal, organic material and a material having high water absorption or is any combination of the above materials.

18. The method for monitoring evaporation of a film according to claim 17, wherein, the rare earth metal is Yb, or the alkali metal is Li, or the alkaline earth metal is Ca or Mg, or the material having high water absorption is alkali metal oxide or alkaline earth metal oxide.

19. The method for monitoring evaporation of a film according to claim 11, wherein, a quartz film thickness gauge is employed in the thickness measuring step.

20. A method for evaporating a film, wherein, evaporation of the film is monitored by using the method for monitoring evaporation of a film according to any one of claim 11.
